(19) United States
(12) Patent Application Publication
(10) Pub. No.: US 2024/0113731 A1
(43) Pub. Date: Apr. 4, 2024

(54) GHOST KEY PREVENTING CIRCUIT

(71) Applicant: Primax Electronics Ltd., Taipei (TW)

(72) Inventors: Chih-Chen Chang, Taipei (TW); Yi-Liang Chen, Taipei (TW); Yu-Ting Lo, Taipei (TW)

(21) Appl. No.: 18/093,501

(22) Filed: Jan. 5, 2023

(30) Foreign Application Priority Data
Oct. 4, 2022 (TW) 111137654

(51) Int. Cl. H03M 11/00; G06F 3/02

(52) U.S. Cl. CPC H03M 11/003; G06F 3/0202

(57) ABSTRACT

A ghost key preventing circuit includes plural driving lines, plural sensing lines, plural key switches, plural bias resistors and a controller. The plural driving lines and the plural sensing lines are collaboratively formed as a matrix circuit. The plural key switches are included in the matrix circuit. The plural bias resistors are connected with the corresponding sensing lines. When the key switch of a specified switch circuit is turned on, a divided voltage is generated and outputted from the specified switch circuit. The controller judges whether the key switch of the specified switch circuit is normally turned on or the key switch is a ghost key according to the divided voltage.

### FIELD OF THE INVENTION

The present invention relates to a ghost key preventing circuit, and more particularly to a ghost key preventing circuit for a keyboard device.

### BACKGROUND OF THE INVENTION

As known, a keyboard circuit of a keyboard device mainly comprises plural key switches and a processor. The processor is installed within the keyboard device. Conventionally, there are two approaches of electrically connecting the plural key switches with the processor. In accordance with a first approach, the output wires of all key switches are individually connected to the processor. Since this approach needs a great number of output wires, it is difficult to install the output circuits.

In accordance with the second approach, plural signal lines are arranged in a matrix to define a matrix circuit. Moreover, plural key switches are arranged side by side and installed in the matrix circuit. Consequently, each signal line is connected with plural key switches. As a consequence, the complexity of the electrical connection between the plural key switches and the microprocessor is largely reduced.

Generally, the processor of the keyboard device determines whether a specified key switch is pressed and triggered by the user according to the result of judging whether an electric signal is transmitted through the key switch. Normally, in case that the key switch is turned off, the electric signal cannot be transmitted through the key switch. Since no electric signal transmitted through the key switch is detected, the processor determines that the key switch has not been pressed and triggered. Under this circumstance, the key signal is not generated. Normally, in case that the key switch is turned on, the electric signal will be transmitted through the key switch. Since the electric signal transmitted through the key switch is detected, the processor determines that the key switch has been pressed and triggered. Under this circumstance, the key signal is generated.

However, since the plural key switches are densely arranged on the same matrix circuit, some drawbacks occur. For example, the signal lines connected with a specified key switch are possibly interfered by the signal lines that are connected with the adjacent key switches. When the adjacent key switches are pressed and triggered, a small amount of electric signal is possibly transmitted through the specified key switch even if the specified key switch is not pressed and triggered. Due to the small amount of electric signal, the processor may misjudge that the key switch is triggered. Consequently, even if the key switch is not pressed, the processor generates the corresponding key signal. This is also called as a ghost key phenomenon.

For avoiding the ghost key phenomenon, the keyboard device is further equipped with plural diodes. Each diode is located near the corresponding key switch. Since the current is allowed to flow in one direction through the arrangement of the diodes, the above-mentioned ghost key phenomenon can be avoided. However, the arrangement of the diodes near the corresponding key switches still has some drawbacks. For example, since the diode is not cost-effective, the cost of the keyboard device is increased.

### SUMMARY OF THE INVENTION

For solving the drawbacks of the conventional technologies, the present invention provides a ghost key preventing circuit for a keyboard device. When compared with the conventional technologies, the ghost key preventing circuit of the present invention is more cost-effective. In accordance with the technical concepts of the ghost key preventing circuit of the present invention, a switch circuit with a key switch and a corresponding bias resistor are electrically connected with each other to define an electric connection path. Due to the electric connection path, a divided voltage is generated when the key switch is turned on. According to the divided voltage, a controller determines whether the key switch is indeed triggered.

In accordance with an aspect of the present invention, a ghost key preventing circuit is provided. The ghost key preventing circuit includes plural driving lines, plural sensing lines, plural key switches, plural bias resistors and a controller. The plural driving lines are discretely arranged. The plural sensing lines are discretely arranged. The plural driving lines and the plural sensing lines are arranged in a matrix and collaboratively formed as a matrix circuit. Moreover, plural switch circuits are defined by the plural key switches, the plural driving lines and the plural sensing lines collaboratively. Each of the plural key switches is electrically connected with a corresponding driving line of the plural driving lines and a corresponding sensing line of the plural sensing lines. Each of the plural key switches, the corresponding driving line and the corresponding sensing line are collaboratively formed as a corresponding switch circuit of the plural switch circuits. A first terminal of each bias resistor of the plural bias resistors is electrically connected with the corresponding sensing line. A second terminal of each bias resistor of the plural bias resistors is connected to a ground terminal. The controller is electrically connected with the plural driving lines and the plural sensing lines. Each switch circuit of the plural switch circuits and the corresponding bias resistor are electrically connected with each other to form an electric connection path. When the key switch of a specified switch circuit is turned on, a divided voltage is generated and outputted from the specified switch circuit. The controller judges whether the key switch of the specified switch circuit is normally turned on according to the divided voltage.

In an embodiment, the key switches connected with each of the plural driving lines are electrically connected with different sensing lines, respectively.

In an embodiment, at a first time point, the controller provides a working voltage to a first driving line of the plural driving lines, and the divided voltages from the switch circuits connected with the first driving line are transmitted through the corresponding sensing lines. Moreover, at a second time point, the controller provides the working voltage to a second driving line of the plural driving lines, and the divided voltages from the switch circuits connected with the second driving line are transmitted through the corresponding sensing lines.

In an embodiment, the working voltage is Vin, and the first voltage range is from 0.228×Vi to 0.5×Vin.

In an embodiment, the working voltage is Vin, and the second voltage range is 0.06×Vin to 0.226×Vin.

In an embodiment, the working voltage is 5V.

In an embodiment, the first voltage range is from 1.14V to 2.5V.

In an embodiment, the second voltage range is 0.32V to 1.13V.

In an embodiment, each of the plural switch circuits further includes a resistor, and a resistance of the resistor is equal to or nearly equal to a resistance of the corresponding bias resistor.

In an embodiment, the controller includes a multiplexer, an analog-to-digital converter and a processor. The multiplexer is electrically connected with the plural sensing lines. The analog-to-digital converter is electrically connected with the multiplexer. The processor is electrically connected with the multiplexer and the analog-to-digital converter.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic circuit diagram illustrating a ghost key preventing circuit for a keyboard device according to an embodiment of the present invention;

FIG. 2 is a schematic circuit diagram illustrating a portion of the ghost key preventing circuit when one key switch is normally turned on; and

FIG. 3 is a schematic circuit diagram illustrating the use of the ghost key preventing circuit of the present invention to prevent from the ghost key phenomenon.

### DETAILED DESCRIPTION OF THE PREFERRED EMBODIMENT

The present invention will now be described more specifically with reference to the following embodiments and accompanying drawings.

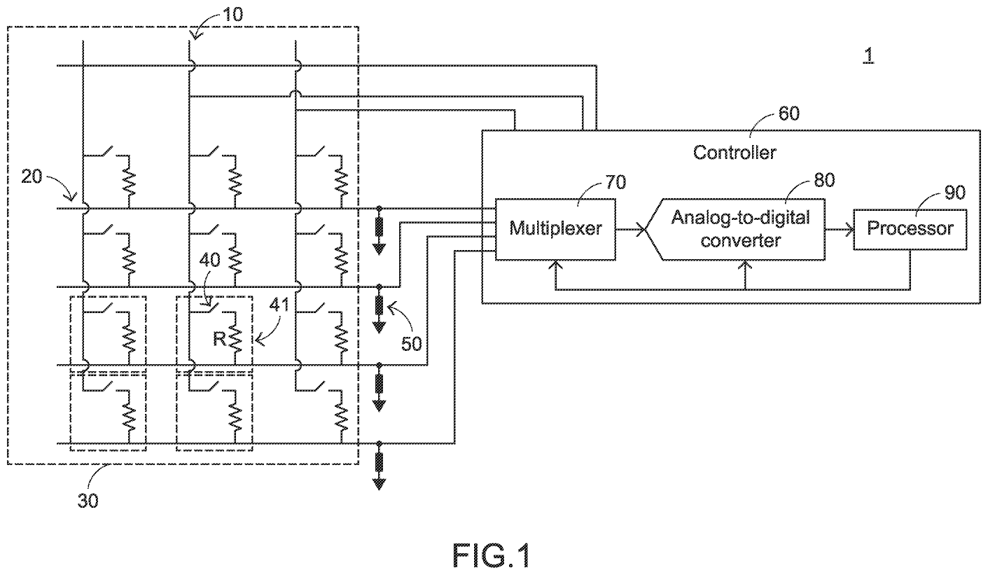

FIG. 1 is a schematic circuit diagram illustrating a ghost key preventing circuit for a keyboard device according to an embodiment of the present invention.

In an embodiment, the ghost key preventing circuit 1 comprises plural driving lines 10, plural sensing lines 20, plural key switches 40, plural bias resistors 50 and a controller 60. The controller 60 comprises a processor 90. The plural driving lines 10 are discretely arranged along a vertical direction. The plural sensing lines 20 are discretely arranged along a horizontal direction. The plural driving lines 10 and the plural sensing lines 20 are arranged in a matrix and collaboratively formed as a matrix circuit 30.

The plural key switches 40 are included in the matrix circuit 30 to define plural switch circuits 41. Particularly, each key switch 40 is electrically connected with a corresponding driving line 10 of the plural driving lines 10 and a corresponding sensing line 20 of the plural sensing lines 20 in the matrix circuit 30. Consequently, each key switch 40, the corresponding driving line 10 and the corresponding sensing line 20 are collaboratively formed as one switch circuit 41. In other words, each driving line 10 is electrically connected with plural key switches 40, and the key switches 40 connected with the driving line 10 are electrically connected with different sensing lines 20, respectively.

In case that a specified key switch 40 is not pressed down by the user, the specified key switch 40 is turned off. In case that the specified key switch 40 is pressed down by the user, the specified key switch 40 is turned on. As shown in FIG. 1, each key switch 40 further comprises a resistor R. When any key switch 40 is pressed down by the user and the key switch 40 is turned on, the key switch 40 and the corresponding resistor R are connected with each other in series. That is, the key switch 40 and the corresponding resistor R are serially connected between the corresponding driving line 10 and the corresponding sensing line 20. Preferably but not exclusively, the resistor R is a resistive element, an equivalent resistive circuit or any other appropriate element with required resistance.

Each of the plural bias resistors 50 is electrically with a corresponding sensing line 20. In other words, the plural bias resistors 50 are electrically connected with the plural sensing lines 20, respectively.

In addition to the processor 90, the controller 60 further comprises a multiplexer 70 and an analog-to-digital converter 80. The multiplexer 70 is electrically connected with the plural sensing lines 20. The analog-to-digital converter 80 is electrically connected with the multiplexer 70. The processor 90 is electrically connected with the multiplexer 70 and the analog-to-digital converter 80.

The controller 60 provides a working voltage to the plural driving lines 10 of the matrix circuit 30 sequentially and periodically. For example, the working voltage is a voltage for powering a general keyboard device in a normal working state. After the working voltage is provided to the driving line 10, the working voltage is provided to the corresponding switch circuits 41 of the matrix circuit 30. Then, the switch circuits 41 connected with the driving line 10 generate a corresponding output voltage to the corresponding sensing line 20. For example, if the key switch 40 of a specified switch circuit 41 is turned off, the output voltage from the switch circuit 41 is zero. Whereas, if the key switch 40 of the specified switch circuit 41 is turned on, the resistor R of the switch circuit 41 and the corresponding bias resistor 50 are serially connected with each other and collaboratively formed as a voltage divider. After the working voltage is subjected to voltage division by the voltage divider, the output voltage from the switch circuit 41 can be obtained according to a voltage divider rule. In this context, the output voltage outputted from the switch circuit 41 and obtained according to the voltage divider rule is also referred as a divided voltage. For example, in case that the resistance of the resistor R of the switch circuit 41 and the resistance of the corresponding bias resistor 50 are equal or nearly equal, the divided voltage is equal to or nearly equal to a half of the working voltage. The divided voltage is transmitted to the multiplexer 70 through the corresponding sensing line 20.

The operating principles of the ghost key preventing circuit 1 will be described in more details as follows.

Firstly, at a first time point, the controller 60 provides the working voltage to a first driving line 10 of the plural driving lines 10. After the working voltage is provided to the first driving line 10, the working voltage is provided to the plural switch circuits 41 that are connected with the first driving line 10. Then, each of the plural switch circuits 41 connected with the first driving line 10 generate a corresponding output voltage to the corresponding sensing line 20. If the key switch 40 of a specified switch circuit 41 is turned off, the output voltage from the switch circuit 41 is zero. If the key switch 40 of the specified switch circuit 41 is turned on, the resistor R of the switch circuit 41 and the corresponding bias resistor 50 are serially connected with each other and collaboratively formed as a voltage divider. After the working voltage is subjected to voltage division by the voltage divider, the output voltage from the switch circuit 41 can be obtained according to the voltage divider rule. Meanwhile, the output voltage (i.e., the divided voltage) is transmitted to the controller 60 through the corresponding sensing line 20 in order for judgement.

Then, at a second time point, the controller 60 provides the working voltage to a second driving line 10 of the plural driving lines 10. After the working voltage is provided to the second driving line 10, the working voltage is provided to the plural switch circuits 41 that are connected with the second driving line 10. Then, each of the plural switch circuits 41 connected with the second driving line 10 generate a corresponding output voltage to the corresponding sensing line 20. If the key switch 40 of a specified switch circuit 41 is turned off, the output voltage from the switch circuit 41 is zero. If the key switch 40 of the specified switch circuit 41 is turned on, the resistor R of the switch circuit 41 and the corresponding bias resistor 50 are serially connected with each other and collaboratively formed as a voltage divider. After the working voltage is subjected to voltage division by the voltage divider, the output voltage from the switch circuit 41 can be obtained according to the voltage divider rule. Meanwhile, the output voltage (i.e., the divided voltage) is transmitted to the controller 60 through the corresponding sensing line 20 in order for judgement.

The above procedures are repeatedly done. Consequently, the switch circuits 41 connected with the other driving lines 10 will successively generate the output voltages (or divided voltages) to the corresponding sensing lines 20 at different time points.

The divided voltages from the plural sensing lines 20 are received by the multiplexer 70. These divided voltages are successively transmitted from the multiplexer 70 to the analog-to-digital converter 80. Moreover, these divided voltages are successively transmitted from the analog-to-digital converter 80 to the processor 90 in order to be judged by the processor 90.

The processor 90 judges whether the key switches 40 are normally turned on according to the divided voltages from the corresponding sensing lines 20. For example, if the divided voltage lies in a first voltage range, the processor 90 judges that the key switch 40 of the corresponding switch circuit 41 is normally turned on. Under this circumstance, the key signal corresponding to this key switch 40 is generated.

On the other hand, if the divided voltage lies in a second voltage range, the processor 90 judges that the key switch 40 of the corresponding switch circuit 41 is turned off. The second voltage range is lower than the first voltage range, but higher than zero. Moreover, if the divided voltage lies in the second voltage range, the corresponding key switch 40 is regarded as a ghost key. Under this circumstance, the key signal corresponding to this key switch 40 will not be generated.

In an embodiment, the first voltage range is from 0.228×Vi to 0.5×Vin, and the second voltage range is 0.06×Vin to 0.226×Vin, wherein Vin is the working voltage. In an embodiment, the working voltage is 5V. In other words, the first voltage range is from 1.14V to 2.5V, and the second voltage range is 0.32V to 1.13V. If the divided voltage is in the range between 1.14V and 2.5V, the processor 90 judges that the switch circuit 41 generating the divided voltage is normally turned on. Under this circumstance, the key signal is generated. Whereas, if the divided voltage is lower than 1.13V, the processor 90 judges that the switch circuit 41 generating the divided voltage is turned off and the key switch 40 corresponding to the switch circuit 41 is not triggered. Under this circumstance, the key signal will not be generated.

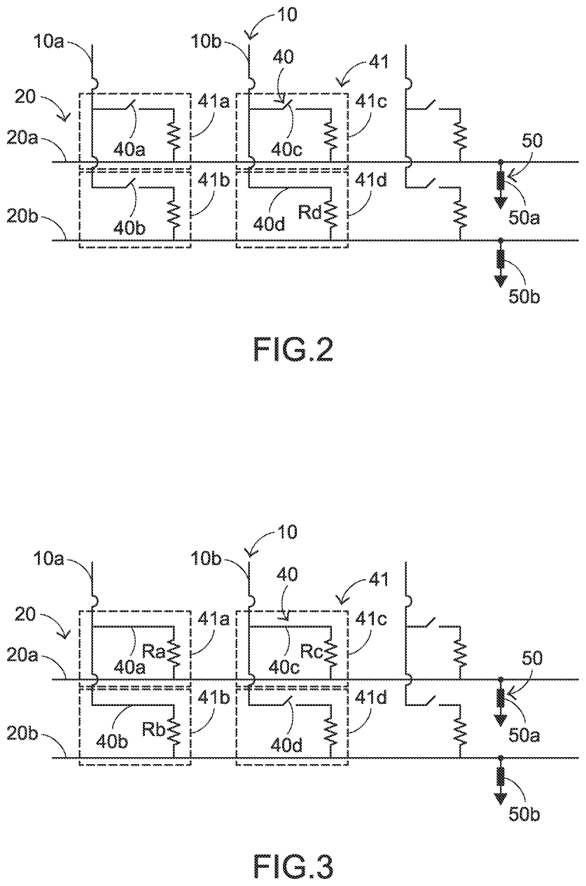

FIG. 2 is a schematic circuit diagram illustrating a portion of the ghost key preventing circuit when one key switch is normally turned on. FIG. 3 is a schematic circuit diagram illustrating the use of the ghost key preventing circuit of the present invention to prevent from the ghost key phenomenon. For succinctness, only some components of the ghost key preventing circuit are shown in the drawings.

For example, a first driving line 10a and a second driving line 10b of the plural driving lines 10 and a first sensing line 20a and a second sensing line 20b of the plural sensing lines 20 in a matrix arrangement are shown in the drawings.

Moreover, plural key switches 40 are connected with the first driving line 10a, the second driving line 10b, the first sensing line 20a and the second sensing line 20b to define plural switch circuits 41. The plural key switches 40 include a first key switch 40a, a second key switch 40b, a third key switch 40c and a fourth key switch 40d. The first key switch 40a is electrically connected with the first driving line 10a and the first sensing line 20a to define a first switch circuit 41a. The second key switch 40b is electrically connected with the first driving line 10a and the second sensing line 20b to define a second switch circuit 41b. The third key switch 40c is electrically connected with the second driving line 10b and the first sensing line 20a to define a third switch circuit 41c. The fourth key switch 40d is electrically connected with the second driving line 10b and the second sensing line 20b to define a fourth switch circuit 41d.

The plural bias resistors 50 include a first bias resistor 50a and a second bias resistor 50b. The first terminal of the first bias resistor 50a is electrically connected with the first sensing line 20a. The second terminal of the first bias resistor 50a is electrically connected with the ground terminal. The first terminal of the second bias resistor 50b is electrically connected with the second sensing line 20b. The second terminal of the second bias resistor 50b is electrically connected with the ground terminal.

Please refer to FIG. 2. As shown in FIG. 2, the key switches 40 are in the normal state, and one of the key switches 40 is normally turned on. For example, the working voltage is 5V. In this situation, the fourth switch circuit 41d is turned on.

At a first time point, the controller 60 provides the working voltage to the first driving line 10a. The first key switch 40a and the second key switch 40b connected with the first driving line 10a are turned off. Consequently, at the first time point, the output voltage transmitted through the first sensing line 20a is zero, and the output voltage transmitted through the second sensing line 20b is zero. Under this circumstance, the processor 90 judges that the first key switch 40a and the second key switch 40b are turned off. Consequently, the key signals corresponding to the first key switch 40a and the second key switch 40b will not be generated.

At a second time point, the controller 60 provides the working voltage to the second driving line 10b. The third key switch 40c connected with the second driving line 10b is turned off. Consequently, at the second time point, the output voltage transmitted through the first sensing line 20a is zero. The fourth key switch 40d connected with the second driving line 10b is turned on. After the working voltage is subjected to voltage division by the voltage divider composed of the resistor Rd of the fourth switch circuit 41d and the second bias resistor 50b, the divided voltage from the fourth switch circuit 41d is obtained according to the voltage divider rule. Assuming that the resistance of the resistor Rd of the fourth switch circuit 41d and the resistance of the second bias resistor 50b are equal, the divided voltage generated by the fourth switch circuit 41d and outputted to the second sensing line 20b is 2.5V. According to the divided voltage from the fourth switch circuit 41d, the processor 90 judges that the fourth key switch 40d is turned on. Under this circumstance, the key signal corresponding to the fourth key switch 40d is generated.

Please refer to FIG. 3. As shown in FIG. 3, a ghost key phenomenon of the key switches 40 is generated. For example, the working voltage is 5V. In this situation, the first key switch 40a, the second key switch 40b and the third key switch 40c are turned on, but the fourth key switch 40d is turned off.

At a first time point, the controller 60 provides the working voltage to the first driving line 10a. The first key switch 40a and the second key switch 40b connected with the first driving line 10a are turned on. After the working voltage is subjected to voltage division by the voltage divider composed of the resistor Ra of the first switch circuit 41a and the first bias resistor 50a, the divided voltage from the first switch circuit 41a is obtained according to the voltage divider rule. Assuming that the resistance of the resistor Ra of the first switch circuit 41a and the resistance of the first bias resistor 50a are equal, the divided voltage generated by the first switch circuit 41a and outputted to the first sensing line 20a is 2.5V. In other words, the divided voltage from the first switch circuit 41a lies in the first voltage range. Similarly, after the working voltage is subjected to voltage division by the voltage divider composed of the resistor Rb of the second switch circuit 41b and the second bias resistor 50b, the divided voltage from the second switch circuit 41b is obtained according to the voltage divider rule. Assuming that the resistance of the resistor Rb of the second switch circuit 41b and the resistance of the second bias resistor 50b are equal, the divided voltage generated by the second switch circuit 41b and outputted to the second sensing line 20b is 2.5V. In other words, the divided voltage from the second switch circuit 41b also lies in the first voltage range. According to the divided voltages from the first switch circuit 41a and the second switch circuit 41b, the processor 90 judges that the first key switch 40a and the second key switch 40b are turned on. Under this circumstance, the key signals corresponding to the first key switch 40a and the second key switch 40b are generated.

At a second time point, the controller 60 provides the working voltage to the second driving line 10b. The third key switch 40c connected with the second driving line 10b is turned on. Since the first switch circuit 41a and the second switch circuit 41b are also turned on, the working voltage provided to the third key switch 40c is subjected to voltage division through two electric connection paths. The first electric connection path is defined by the resistor Ra of the first switch circuit 41a and the first bias resistor 50a collaboratively. The second electric connection path is defined by the resistor Ra of the first switch circuit 41a, the resistor Rb of the second switch circuit 41b, the resistor Rc of the third key switch 40c and the second bias resistor 50b. It is assumed that the resistance of the resistor Ra of the first switch circuit 41a, the resistance of the resistor Rb of the second switch circuit 41b, the resistance of the resistor Rc of the third switch circuit 41c, the resistance of the first bias resistor 50a and the resistance of the second bias resistor 50b are equal. In the first electric connection path, the divided voltage generated by the third switch circuit 41c and outputted to the first sensing line 20a is 2.14V. In other words, the divided voltage from the third switch circuit 41c also lies in the first voltage range. According to the divided voltage, the processor 90 judges that the third key switch 40c is turned on. Under this circumstance, the key signal corresponding to the third key switch 40c is generated.

Please refer to FIG. 3 again. As mentioned above, the first key switch 40a, the second key switch 40b and the third key switch 40c are turned on, but the fourth key switch 40d is turned off. In the second electric connection path, the divided voltage generated by the fourth key switch 40d and outputted to the second sensing line 20b is 0.714V. In other words, the divided voltage from the fourth key switch 40d lies in the second voltage range. According to the divided voltage, the processor 90 judges that the fourth key switch 40d is turned off. Under this circumstance, the key signal corresponding to the fourth key switch 40d is not generated. As a consequently, the ghost key phenomenon can be effectively avoided.

From the above descriptions, the present invention provides a ghost key preventing circuit for a keyboard device. The ghost key preventing circuit comprises a matrix circuit and plural bias resistors. When a driving line of the matrix circuit receives a working voltage, the switch circuits connected with the driving line generate divided voltages to the corresponding sensing line. According to the magnitudes of the divided voltages, the processor judges whether the switch circuits connected with the driving line are related to the on-state switch circuit or the ghost keys. Since the ghost key preventing circuit is equipped with the matrix circuit, the number of the output lines is largely reduced. Moreover, since the ghost key preventing circuit is not equipped with the diodes, the fabricating cost of the ghost key preventing circuit is largely reduced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

1. A ghost key preventing circuit, comprising:
plural driving lines, wherein the plural driving lines are discretely arranged;
plural sensing lines, wherein the plural sensing lines are discretely arranged, and the plural driving lines and the plural sensing lines are arranged in a matrix and collaboratively formed as a matrix circuit;
plural key switches, wherein plural switch circuits are defined by the plural key switches, the plural driving lines and the plural sensing lines collaboratively, wherein each of the plural key switches is electrically connected with a corresponding driving line of the plural driving lines and a corresponding sensing line of the plural sensing lines, and each of the plural key switches, the corresponding driving line and the corresponding sensing line are collaboratively formed as a corresponding switch circuit of the plural switch circuits;
plural bias resistors, wherein a first terminal of each bias resistor of the plural bias resistors is electrically connected with the corresponding sensing line, and a second terminal of each bias resistor of the plural bias resistors is connected to a ground terminal; and
a controller electrically connected with the plural driving lines and the plural sensing lines,
wherein each of the plural switch circuits and the corresponding bias resistor are electrically connected with each other through the corresponding sending line to form an electric connection path, wherein when the key switch of a specified switch circuit is turned on, a divided voltage is generated and outputted from the specified switch circuit, wherein the controller judges whether the key switch of the specified switch circuit is normally turned on according to the divided voltage;
wherein if the divided voltage lies in a first voltage range, the controller judges that the key switch of the corresponding switch circuit is normally turned on, if the divided voltage lies in a second voltage range, the controller judges that the key switch of the corresponding switch circuit is turned off;
wherein each of the plural switch circuits further comprises a resistor, and a resistance of the resistor is equal to or nearly equal to a resistance of the corresponding bias resistor;
wherein the resistor and the first terminal of the corresponding bias resistor are directly and electrically connected together through the corresponding sensing line.

2. The ghost key preventing circuit according to claim 1, wherein the key switches connected with each of the plural driving lines are electrically connected with different sensing lines, respectively.

3. The ghost key preventing circuit according to claim 1, wherein at a first time point, the controller provides a working voltage to a first driving line of the plural driving lines, and the divided voltages from the switch circuits connected with the first driving line are transmitted through the corresponding sensing lines, wherein at a second time point, the controller provides the working voltage to a second driving line of the plural driving lines, and the divided voltages from the switch circuits connected with the second driving line are transmitted through the corresponding sensing lines, wherein the working voltage is a fixed constant value.

4. The ghost key preventing circuit according to claim 3, wherein the working voltage is Vin, and the first voltage range is from 0.228×Vin to 0.5×Vin.

5. The ghost key preventing circuit according to claim 3, wherein the working voltage is Vin, and the second voltage range is 0.064×Vin to 0.226×Vin.

6. The ghost key preventing circuit according to claim 3, wherein the working voltage is 5V.

7. The ghost key preventing circuit according to claim 6, wherein the first voltage range is from 1.14V to 2.5V.

8. The ghost key preventing circuit according to claim 6, wherein the second voltage range is 0.32V to 1.13V.

9. (canceled)

10. The ghost key preventing circuit according to claim 1, wherein the controller comprises a multiplexer, an analog-to-digital converter and a processor, wherein the multiplexer is electrically connected with the plural sensing lines, the analog-to-digital converter is electrically connected with the multiplexer, and the processor is electrically connected with the multiplexer and the analog-to-digital converter.
